(19) United States
(12) Patent Application Publication
(10) Pub. No.: US 2009/0242411 A1
(43) Pub. Date: Oct. 1, 2009

(54) POLYIMIDE-METAL LAMINATED BODY AND POLYIMIDE CIRCUIT BOARD

(75) Inventors: Tadahiro Yokozawa, Ichihara-shi (JP); Hiroaki Yamaguchi, Ichihara-shi (JP); Keita Banba, Ichihara-shi (JP); Masao Okubo, Ichihara-shi (JP); Sumiko Okubo, Ichihara-shi (JP)

Correspondence Address: IP GROUP OF DLA PIPER LLP (US), ONE LIBERTY PLACE, 1650 MARKET ST, SUITE 4900, PHILADELPHIA, PA, 19103, US

(73) Assignee: Ube Industries, Ltd,, Ube-shi (JP)

(21) Appl. No.: 12/465,922

(22) Filed: May 14, 2009

Related U.S. Application Data
(63) Continuation of application No. 10/585,533, filed on Jul. 10, 2006.

(30) Foreign Application Priority Data
Jan. 13, 2004 (JP) 2004-005651

(51) Int. Cl. H05K 3/00; C25D 5/02

(52) U.S. Cl. 205/125; 205/187

(57) ABSTRACT

A process for producing a polyimide-metal laminated body includes forming a metal conductive layer on a polyimide film having a ceramic-modified or pseudoceramic-modified surface with a wet plating process which includes forming at least a ground treatment layer by electroless plating, conducting electroless metal plating and conducting electrolytic copper plating.

### RELATED APPLICATIONS

This application is a continuation of U.S. application Ser. No. 10/585,533, filed Jul. 10, 2006, which is a §371 of PCT/JP2005/000448, with an international filing date of Jan. 11, 2005 (WO 2005/068185 A1, published Jul. 28, 2005), which is based on Japanese Patent Application No. 2004-005651, filed Jan. 13, 2004.

### TECHNICAL FIELD

This disclosure relates to a laminated body and polyimide circuit board comprising a polyimide base material and a metal layer, particularly to a polyimide-metal laminated body and polyimide circuit board having a conductive layer formed on a polyimide film by wet plating and, especially, to a flexible polyimide-metal laminated body and polyimide circuit board.

### BACKGROUND

Conventional polyimide laminated boards have been manufactured by laminating a thermoplastic polyimide on one or both sides of a base polyimide layer and thermocompression bonding a copper foil therewith, or by casting a polyimide precursor onto a copper foil and firing it. However, as the copper foil is roughened to improve the cohesion between the copper foil and polyimide, this method has not been satisfactory for achieving high precision and for high-frequency characteristics. To solve this problem there have been developed and manufactured laminated bodies having a seed metal layer on a polyimide film, a ground conductive metal layer formed by a vacuum vapor deposition or sputtering process, and a conductive layer formed by electrolytic metal plating using the ground conductive metal layer as the electrode, with a flat interface between the polyimide film and conductive metal layer.

However, the manufacturing steps which are combined in a vapor deposition process and wet process in this method are complicated. Particularly, when the conductive layer is formed on both sides by a vapor deposition process, any generated gas is virtually unable to escape from the heated polyimide and the quality is thereby reduced.

On the other hand, methods are also being investigated for accumulating electrolytic copper platings by forming an electroless copper plating layer or a ground conductive layer by a direct plating system, after pre-treatment such as hydrophilic treatment of the polyimide base material. However, this has been limited to front/back side connection purposes such as blind vias or throughhole vias, as it has been difficult to accomplish film surface plating over the wide areas necessary for circuit formation.

Chemical plating of polyimides is basically difficult, and adequate cohesive strength has not been possible even when the plating is formed by complicated pretreatment and post-treatment. In addition, the cohesive strength is often significantly reduced by continuing an aging treatment at high temperature. Proposals aimed at overcoming this drawback include chemical bonding of low molecular compounds having affinity for the plating metal onto the polyimide film surface (Japanese Unexamined Patent Publication No. 2002-208768), and formation of a separate resin coating capable of chemical plating onto the polyimide film surface (Japanese Unexamined Patent Publication No. 2001-168496).

These proposals require treatment in a separate step from the polyimide film formation, and therefore the entire fabrication process for the metal foil laminated body is complex and the heat resistance of the formed surface-modified layer is not always sufficient (Japanese Unexamined Patent Publication No. 2003-136632 and Japanese Unexamined Patent Publication No. 2003-200527). The aforementioned publications propose techniques for forming metal layers by chemical plating of finely-dispersed silica polyimide films. However, while these methods employ common electroless copper plating and yield a satisfactory initial peel strength, there is no mention regarding the behavior of the peel strength in response to a high-temperature aging treatment. In addition, as control of the linear expansion coefficient of the polyimide film is not considered, it is difficult to maintain dimensional stability when the metal foil laminated body is used as a circuit board material (Japanese Unexamined Patent Publication No. 2000-289167 and Japanese Unexamined Patent Publication No. 2002-64252).

The aforementioned publications propose techniques for in-line incorporation of chemical plating catalysts into the film surface during the polyimide film formation. This simplifies the manufacturing steps for the metal foil laminated body, and also produces excellent cohesive force between the metal foil and the polyimide film. However, the chemical plating catalyst remains between the lines even after circuit formation, thereby impairing the electrical insulating property.

It could therefore be helpful to provide a laminated body and polyimide circuit board that do not require a complex vacuum process, have satisfactory cohesion in wet plating steps, maintain a practical cohesion even after high temperature aging treatment, and exhibit a satisfactory electrical insulating reliability.

### SUMMARY

We provide a process for producing a polyimide-metal laminated body including forming a metal conductive layer on a polyimide film having a ceramic-modified or pseudoceramic-modified surface with a wet plating process which includes forming at least a ground treatment layer by electroless plating, conducting electroless metal plating and conducting electrolytic copper plating.

We also provide a process for producing a polyimide circuit board by forming a circuit on a polyimide film having a ceramic-modified or pseudoceramic-modified surface by a wet plating process, wherein the wet plating process comprises at least a ground treatment layer forming step for electroless plating, an electroless metal plating step and an electrolytic copper plating step, and the circuit is formed by forming a photosensitive resist layer before the electrolytic copper plating step or during the electrolytic copper plating step and then removing the resist at pattern-forming sections by a photoprocess and growing electrolytic copper plating at the removed sections.

It is possible to obtain polyimide-metal laminated bodies and polyimide circuit boards which do not require a complicated vacuum process for vapor deposition of the ground metal on the polyimide film, and which have satisfactory cohesion in wet plating steps, maintain practical cohesion even after high temperature aging treatment, and exhibit satisfactory electrical insulating reliability.

### BRIEF DESCRIPTION OF THE DRAWINGS

FIG. 1 shows an example of a typical fabrication process used to obtain a polyimide-metal laminated body.

FIG. 2 shows a first process as an example of a typical fabrication process used to obtain a polyimide double-sided circuit board.

FIG. 3 shows a second process as an example of a typical fabrication process used to obtain a polyimide double-sided circuit board.

FIG. 4 shows a third process as an example of a typical fabrication process used to obtain a polyimide double-sided circuit board.

FIG. 5 is a graph showing the results of measuring the 90° peel strength after prolonged aging of the polyimide-copper laminated body obtained in Example 1 in an oven with an atmosphere of 150° C.

FIG. 6 is a graph showing the results of an insulation reliability test wherein a solder resist film was formed on a 40 μm pitch comb-shaped electrode fabricated using the polyimide copper laminated body obtained in Example 1, and a 52 V bias voltage was applied in an environment of 85° C., 85% RH.

The electrical insulating resistance was satisfactorily maintained even after 1000 hours.

### DETAILED DESCRIPTION

Preferred aspects of our laminated bodies and circuit boards include:
1) The aforementioned polyimide-metal laminated body wherein the metal conductive layer comprises an electroless copper plating layer and an electrolytic copper plating layer thereover.
2) The aforementioned polyimide-metal laminated body which is further subjected to heat treatment at 100-350° C. for 1 minute to 10 hours after or before the metal plating.
3) The aforementioned polyimide-metal laminated body wherein the initial peel strength of the metal layer of the metal conductive layer with respect to the polyimide film is at least 0.5 kg/cm in a 90° peel test (5 cm/min), and is also at least 0.5 kg/cm even after aging treatment in 150° C. air for 1 week (168 hours).
4) The aforementioned polyimide-metal laminated body wherein the wet plating process accomplishes electroless copper plating of a surface alumina-modified or silica-modified film, after forming, on a ceramic, an electroless metal oxide ground layer or electroless nickel ground layer which can be removed by etching treatment, and thereby allows the cohesion to be improved and oxidation of the copper and polyimide interface to be prevented, to avoid cohesive degradation during overheating.
5) The aforementioned polyimide-metal laminated body wherein the polyimide film has a thermal expansion coefficient of 5×10⁻⁶ to 25×10⁻⁶ cm/cm/° C. (average of MD, TD) at 50-200° C.

Throughout this specification, “ceramic-modified” refers to a state in which a ceramic structure such as an aluminum oxide or silicon oxide is formed on at least a portion of the surface, and “pseudoceramic-modified” will refer to a state in which at least a portion of the surface is a ceramic surface, or contains bonds produced by publicly known pre-treatment, such as aluminum hydroxide or silicon hydroxyl groups, or dangling bonds, and acts essentially as a ceramic surface.

It is important to combine a polyimide base material which has been ceramic-modified or pseudoceramic-modified on at least the surface, with a wet plating process capable of accomplishing metal plating on ceramic. As the surface of the ceramic-modified or pseudoceramic-modified polyimide base material behaves as if a ceramic, it is possible to form a satisfactory metal film by a wet plating process capable of accomplishing metal plating on ceramic, thereby yielding a polyimide-metal laminated body with satisfactory cohesion. In addition, by forming a photosensitive resist layer before the metal plating process or during the metal plating process and then removing the resist at the pattern-forming sections by a photoprocess, growing a conductive metal layer plating at the removed sections and carrying out a suitable publicly-known post-treatment, it is possible to obtain a polyimide circuit board with good cohesion.

There are no particular restrictions on the fabrication process, composition, layer construction, etc. of the polyimide base material which has been ceramic-modified or pseudoceramic-modified on at least the surface, and it may be, as described in Japanese Unexamined Patent Publication No. 11-158276, for example, a base material obtained by doping an aluminum oxide precursor in a polyimide precursor solution and firing it into a film, or by casting an aluminum oxide precursor solution on a self-supporting film obtained from a polyimide precursor solution and firing it.

Alternatively, the polyimide base material which has been ceramic-modified or pseudoceramic-modified on at least the surface may be a base material obtained by mixing aluminum oxide or silicon oxide superfine particles in a polyimide precursor solution, casting the mixture onto a surface and firing. Also, the main chain and/or side chains of the polyimide may include bonds with metal oxides or the like, and there are no restrictions on the form or composition so long as a ceramic-like state is produced on the base material surface. The base material surface does not necessarily have to be completely modified, as it is sufficient if a discrete or mesh pattern is formed in a range which provides adequate cohesive strength during circuit formation.

There are no particular restrictions on the polyimide of the aforementioned polyimide base material, so long as it has a thermal expansion coefficient of 5×10⁻⁶ to 25×10⁻⁶ cm/cm/° C. (the MD, TD or average) at 50-200° C., and for example, it may be obtained from an aromatic tetracarboxylic acid component such as 3,4,3′,4′-biphenyltetracarboxylic dianhydride and/or pyromellitic dianhydride and an aromatic diamine such as paraphenylene diamine, 4,4′-diaminobiphenylether and/or o-tolidine, or by replacing a portion of the aromatic tetracarboxylic acid component and aromatic diamine component with another aromatic tetracarboxylic acid component or aromatic diamine component or aromatic tricarboxylic acid component, such as trimellitic anhydride.

The polyimide base material which has been ceramic-modified or pseudoceramic-modified on at least the surface may be obtained, for example, by coating a self-supporting film obtained from a solution, of a polyamic acid as a polyimide precursor, with a solution comprising a ceramic component such as aluminum oxide or silica, and then drying it to obtain a dry film containing an aluminum component, and then heating the obtained film at a temperature of 420° C. or higher and preferably 430-520° C., and preferably for a period of about 2-30 minutes to complete imidation.

Any aluminum compound which is soluble in polyamic acid solution may be used as the aforementioned aluminum compound. As examples of such aluminum compounds there may be mentioned aluminum oxide, or organic aluminum compounds such as aluminum monoethylacetate diisopropylate, aluminum diethylacetate monoisopropylate, aluminum triacetyl-acetonate, aluminum triethylacetoacetonate, aluminum isopropylate and aluminum butylate, with a preferred organic aluminum compound being aluminum triacetylacetonate.

The self-supporting film may be obtained, for example, by reacting the acid component and diamine component in an organic solvent at below about 100° C., especially 20-60° C., to obtain a polyamic acid solution, using the polyamic acid solution as a dope solution for casting onto a support, drying it at about 70-200° C. to form a thin film, and releasing the film from the support. To facilitate the release, an organic phosphorus compound such as triphenyl phosphite or triphenyl phosphate may be added during the polyamic acid polymerization in a range of 0.01-1% with respect to the solid (polymer) concentration.

The organic solvent used for production of the polyamic acid may be N-methyl-2-pyrrolidone, N,N-dimethylformamide, N,N-dimethylacetamide, N,N-diethylacetamide, dimethylsulfoxide, hexamethylphosphoramide or N-methylcaprolactam. These organic solvents may be used alone or in combinations of two or more.

A basic organic compound may be added to the starting material solution to accelerate the imidation. For example, imidazole, 2-methylimidazole, 1,2-dimmethylimidazole, 2-phenylimidazole, triethylamine or the like may be used during the polyamic acid polymerization in a proportion of 0.1-10 wt % with respect to the solid concentration.

There are no particular restrictions on the wet plating process capable of accomplishing metal plating on ceramic, and for example, the following steps may be employed. A water washing step is included between each treatment.

Wet Plating Process:
1) Degreasing/surface modification step: For example, immersion treatment for 15 seconds to 30 minutes in a surface modifying agent at 25-80° C.
2) Catalyst addition, step: For example, immersion for 5 seconds to 5 minutes using a solution at pH 1-5 containing 1-50 g/L of a sensitizer, for example a water-soluble first silver salt such as silver chloride and 5-100 mL of an acid such as hydrochloric acid, at 10-50° C., followed by immersion for 5 seconds to 5 minutes in a silver activating solution at pH 2-8 containing 0.1-2 g/L of a water-soluble Ag salt (silver nitrate, etc.) for sensitizing, at 10-50° C., and then immersion for 5 seconds to 5 minutes in a palladium activating solution at pH 1-5 containing 0.01-1 g/L of an activator, for example a water-soluble Pd-salt such as Pd chloride and 0.01-1 mL/L of an acid such as, hydrochloric acid, at 10-50° C., for the catalyst addition.
3) Ground treatment layer forming step for electroless plating: Treatment by immersion in a treatment solution comprising 0.001-5 mol/L of zinc ion (zinc nitrate, etc.), 0.00001-0.1 mol/L of indium ion (indium nitrate, etc.) and 0.0001-1 mol/L of an aminoborane complex (dimethylaminoborane, etc.), at 50-90° C. for 1-60 minutes, to form a zinc-containing indium oxide ground layer.
4) Catalyst addition step: For example, immersion in an aqueous solution of a water-soluble metal salt: For example, immersion, spraying or coating with an aqueous solution at pH 1-5 comprising a water-soluble metal salt such as a water-soluble Pd salt (Pd chloride, etc.) at a concentration of 0.01-1 g/L, at 10-80° C. for 5 seconds to 5 minutes.
5) Electroless metal plating step: For example, immersion in a solution at pH 9-14 comprising 0.01-0.5 mol/L of a water-soluble metal salt such as copper sulfate, 0.1-1 mol/L of a reducing agent such as formaldehyde and 0.01-1 mol/L of a chelating agent such as EDTA, at 10-70° C. for 5-60 minutes.
6) Electrolytic copper plating step: Electrolysis in a solution at pH 0.1-2 comprising 0.1-0.5 mol/L of a water-soluble copper salt such as copper sulfate and 1.5-3 mol/L of an acid such as sulfuric acids at 10-30° C. and a cathode current density of 1-4 A/dm², for 5-60 minutes.

As such a process there may be mentioned a method of forming a ground layer by the “Zintra” process by C. Uyemura & Co., Ltd. or the Melplate G/Si process by Meltex Inc., and then accumulating an electrode plating thereover. The “Zintra” process yields metal films with good cohesion on ceramics (soda lime glass), as disclosed in Japanese Unexamined Patent Publication No. 2003-247076.

This process accomplishes formation of a catalyst layer containing Sn, Ag and Pd on a plating base material by chemical solution dipping, followed by formation of a zinc-containing indium hydroxide ground layer by electroless plating, and then dipping in a treatment solution to form a catalyst metal layer for electroless copper plating. The electroless copper plating layer may be used as the electrode for electrolytic copper plating to achieve the necessary film thickness. The Melplate G/Si process (Meltex Inc.) is a process for electroless Ni plating onto ceramics, and the Ni plating may be followed by similar electroless plating and electrolytic copper plating to form a conductive metal layer.

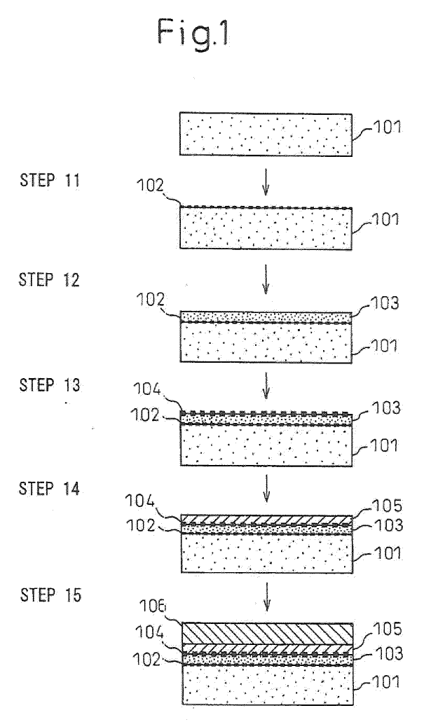

A polyimide-metal laminated body will now be explained with reference to FIG. 1 as an example of a typical fabrication process. In FIG. 1, 101 is a polyimide film which has been pseudoceramic-modified on the surface. In step 11, a catalyst 102 for ground layer formation is added after an ordinary degreasing/washing treatment, and in step 12 a zinc-containing indium hydroxide ground layer 103 is formed by electroless plating. In the subsequent step 13, a catalyst 104 for electroless copper plating is added and then, in step 14, an electrode layer 105 for electrolytic; copper plating is formed by electroless copper plating. Also, in step 15 a conductive metal layer 106 is formed by electrolytic copper plating to obtain a polyimide copper laminated body. Steps 11 to 15 are all wet steps. Incidentally, the zinc-containing indium hydroxide ground layer 103 will sometimes be converted to a zinc-containing indium oxide layer by heat treatment, but the same effect is exhibited.

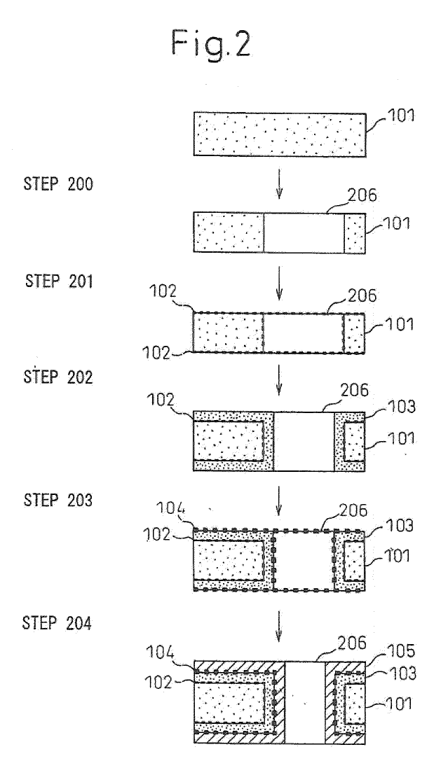

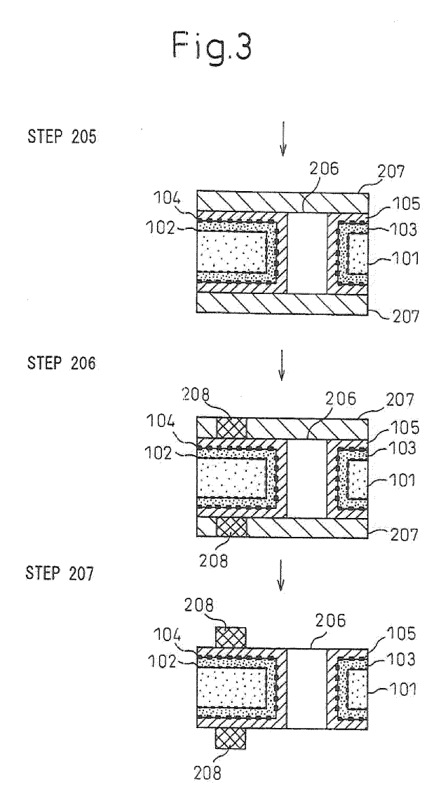

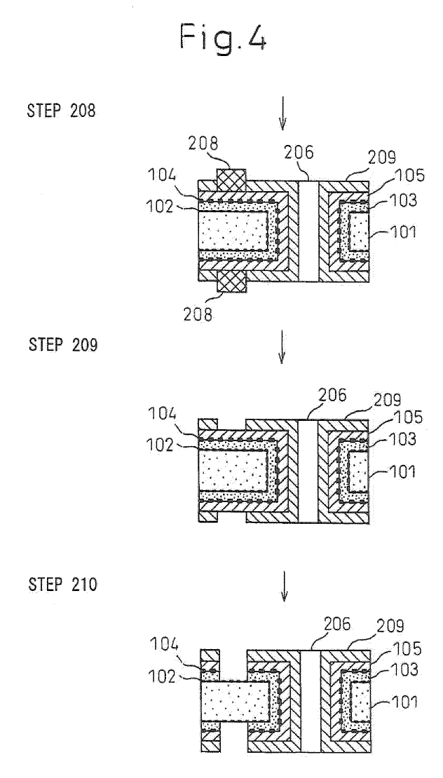

A polyimide double-sided circuit board will now be explained with reference to FIGS. 2 to 4 as an example of a typical fabrication process. This is an example of batch formation of a double-sided circuit. In FIGS. 2 to 4, reference numerals 101 to 105 are the same as in FIG. 1. First, in step 200, a throughhole 206 is opened in the film 101 to allow front/back conduction. The hole forming method may be any one which allows front/back perforation, such as punching, laser working or the like. Steps 201 to 204 are the same as in FIG. 1 except that both sides and the throughholes of the board are simultaneously treated, and correspond to 11 to 14, respectively.

In step 205, a dry film type negative photoresist 207 is attached to the front and back sides of the polyimide base material on which the electrode layer 105 has been formed, for electrolyte copper plating of the front/back and throughholes. In the subsequent step 206, a circuit pattern drawn on the mask is transferred to the photoresist by light exposure for photosensitization of the non-circuit-forming sections 208, and development in step 207 removes the unexposed resist at the circuit-forming sections.

Although a negative-type dry film photoresist was used here to facilitate obtaining a, thick circuit, a positive-type is appropriate so long as the circuit-forming sections are photosensitized, and a liquid photoresist may even be used so, long as the necessary thickness can be obtained. In the subsequent step 208, a conductive layer 209 is formed by electrolytic copper plating for formation of a circuit on the sections from which the resist has been removed. The unwanted resist is removed with an alkali solution in step 209, while in step 210, the unwanted electroless copper plating layer and ground layer at the non-circuit-forming sections are removed by microetching or the like to obtain a double-sided polyimide circuit board.

The plating cohesion in the throughholes will sometimes be reduced when only the surface of the polyimide film is pseudoceramic-modified, but this is not a problem in practice due to integration with the highly cohesive copper layer on the front and back sides. Alt of the steps other than steps 206 and 207 are wet processes.

It is possible to have copper formed as the conductive layer, but the metal is not restricted so long as it is suitable for wet plating; also, an electroless copper plating layer is formed as the conductive layer for electrolytic copper plating in this case as an example of obtaining an adequate conductive layer thickness of satisfactory quality, but electroless plating alone may be employed depending on the necessary performance. Alternatively, electrolytic plating may be carried out alone using the ground layer as the conductive layer, and a metal different from the metal formed by electroless plating may be formed by electrolytic plating as the electrode layer for electrolytic plating. Formation of a ground layer is not essential if the process does not require formation of a ground layer for plating onto ceramics.

The polyimide-metal laminated body has a metal layer on both sides, and preferably the initial peel strength of the metal layer with respect to the polyimide film is at least 0.5 kg/cm in a 90° peel test (5 cm/min), and is also at least 0.5 kg/cm even after aging treatment in 150° C. air for 1 week (168 hours).

This disclosure will now be explained in greater detail through the following examples and comparative examples, with the understanding that the disclosure is in no way limited thereby.

### Reference Example 1

Fabrication of polyimide film ceramic-modified or pseudoceramic-modified on at least the surface.

In a 300 ml glass reactor equipped with a stirrer, nitrogen introduction tube and circulation tube there were added 183 g of N,N-dimethylacetamide and 0.1 g of a phosphorus compound (SEPARU 365-100, product of Chukyo Yushi Co., Ltd.), and after further addition of 10.81 g (0.1000 mole) of paraphenylenediamine while stirring under a nitrogen stream, the reactants were heated to 50° C. to complete dissolution. After slowly adding 29.229 g (0.9935 mole) of 3,3′,4,4′-biphenyltetracarboxylic dianhydride while noting the heat release, reaction was continued for 5 hours while maintaining a temperature of 50° C. Next, 0.2381 g (0.00065 mole) of 3,3′,4,4′-biphenyltetracarboxylic dianhydride was dissolved therein. The obtained polyamic acid solution was a brown viscous solution having a solution viscosity of about 1500 poise at 25° C. The thermal expansion coefficient was 15×10⁻⁶ cm/cm/° C. (average of MD, TD), at 50-200° C., of the single polyimide film layer (25 μm) produced separately from the dope.

The polyamic acid solution was cast and coated on a glass substrate, dried at 150° C. for 10 minutes, released from the substrate, bound onto a frame, coated with a DMAc solution containing 2 wt % of an aluminum chelate compound (ALCH, product of Kawaken Fine Chemical Co., Ltd.), and then heat treated at 200° C. for 3 minutes, 300° C. for 3 minutes and 480° for 4 minutes to obtain a polyimide film with a thickness of 25 μm.

### Reference Example 2

A polyimide film with a thickness of 25 μm and a silica-modified surface was formed according to the method of Reference Example 1, except that silica gel (a dimethylacetamide solution containing 20 wt % of a silica sol component with a mean particle size of 30 nm, product of Nissan Chemical Industries, Ltd.) and a silane coupling agent (KBM-903, product of Shin-Etsu Chemical Co., Ltd.) were used instead of the aluminum-based coating solution in Reference Example 1, to prepare a dimethylacetamide solution comprising 2.5 wt % of the silica sol component and 0.5 wt % of the silane coupling component, as a coating solution.

### Example 1

A ground layer and electroless copper plating layer were accumulated on the polyimide film with a thickness of 25 μm obtained in Referenced Example 1 by the plating process shown in Table 1 (“Zintra” process by C. Uyemura & Co., Ltd.). Also, electrolytic copper plating was carried out in a copper sulfate-based electrolytic plating solution for 30 minutes at a current density of 3 A/dm², and then heat treatment was carried out in a 200° C. oven for 30 minutes to obtain a polyimide copper laminated body with a copper thickness of 10 μm. The results of measuring the 90° peel strength of the obtained polyimide copper laminated body are shown together with the comparative examples in Table 2.

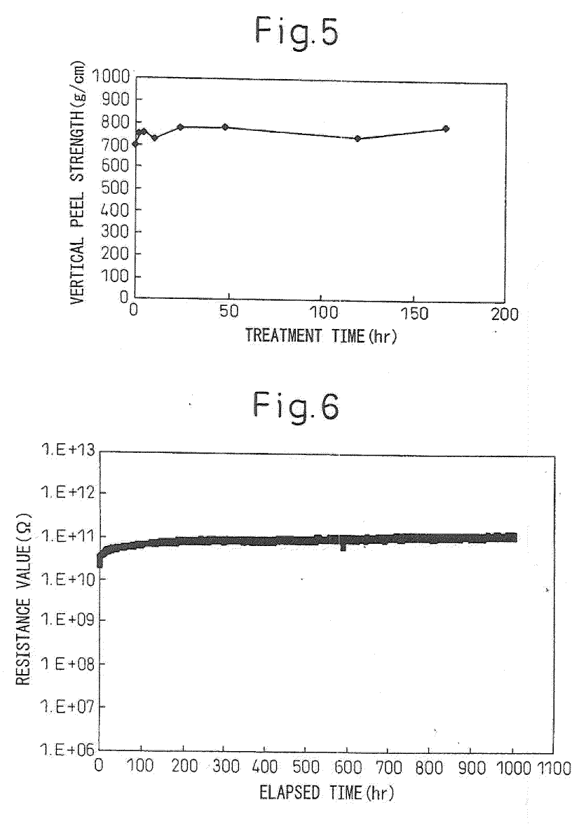

The results of measuring the 90° peel strength after prolonged aging in an oven with a 150° C. atmosphere are shown in FIG. 5. No deterioration in peel strength was seen even after elapse of 168 hours.

The obtained laminated body was also used to form a 40 μm pitch comb-shaped electrode by a publicly known etching process using iron (II) chloride and, then, a solder resist film (FS-510U: product of Ube Industries, Ltd., curing at 150° C. for 1 hour) was formed on the comb-shaped electrode and a bias voltage of 52 V was applied in an environment of 85° C., 85% RH for an insulation reliability test, the results of which are shown in FIG. 6. Absolutely no deterioration in the insulating property was observed even after elapse of 1000 hours.

### Comparative Example 1

A 25 μm-thick polyimide film (UPILEX-S, product of Ube Industries, Ltd.) which had been plasma treated on the surface was used for the same treatment as in Example 1. The copper layer formed, but the cohesive strength was very weak and led to peeling before the peel strength measurement.

### Comparative Example 2

A 25 μm-thick polyimide film (UPILEX-S, product of Ube Industries, Ltd.) was used for the same treatment as in Example 1. Absolutely no copper layer formed.

### Example 2

The film obtained in Reference Example 2 was used for accumulation of a ground layer and an electroless copper plating layer by the plating process shown in Table 1 (“Zintra” process by C. Uyemura & Co., Ltd.). After lamination of a dry film type, photoresist SPG-152 (product of Asahi Chemical Industry Co., Ltd.) with a thickness of 15 μm at a temperature of 70° C. and a pressure of 0.45 MPa, a 40 μm pitch pattern was formed by 160 mJ exposure using a projection printer followed by spray development for 30 seconds at 0.2 MPa using 30° C. 1% sodium carbonate water, for removal of the photoresist at the circuit-forming portions. After ordinary acidic degreasing and acid washing, a copper sulfate-based plating solution was used for 30 minutes of electrolytic plating at a current density of 2 A/dm², to form a circuit pattern with a copper thickness of 8 μm. The dry film resist was peeled using a 1% caustic soda solution, and then an iron chloride-based soft etching solution C-800 (product of Asahi Denka Kogyo K.K.) was sprayed for 1 minute at 0.05 MPa, and the electroless copper layer and ground layer at the non-pattern-formed sections were removed to obtain a polyimide circuit board. After aging in a 150° C. atmosphere for 168 hours, Scotch tape by Minnesota Mining & Manufacturing Co. was used for a pattern peeling test at room temperature, and observation with a 20× stereo-microscope revealed no peeling of the pattern.

TABLE 1

| | | | Temper- | | |
|---|---|---|---|---|---|
| | | | ature | | |
| Step | | Chemical agent | (° C.) | Time | |
| Degreasing, | 1 | “Zintra” MTL-50 | 50 | 5 | min |
| surface | | | | | |
| modification | | | | | |
| Catalyst addition | 2 | “Zintra” MTS-17 | 25 | 30 | sec |
| | 3 | Activator MSA-27 | 25 | 30 | sec |
| | 4 | Activator A-10X | 25 | 30 | sec |
| | Repeat 2-4 | | | | |
| Electroless oxide | 5 | “Zintra” HMT-70 | 65 | 2.5 | min |
| Catalyst addition | 6 | “Zintra” MTS-17 | 25 | 30 | sec |
| | 7 | Activator A-10X | 25 | 30 | sec |
| Electroless Cu | 8 | “Thru-cup” PEA | 36 | 15 | min |

*Ion-exchange water washing was performed between each step.

TABLE 2

| | | Copper laminated body peel | |
|---|---|---|---|
| | | strength g/cm | |
| | Copper layer | | After 150° C., |
| | formation | Initial value | 150 h |
| Example 1 | Good | 700 | 800 |
| Comparative Example 1 | Good | ~0 | — |
| Comparative Example 2 | Poor | — | — |

### INDUSTRIAL APPLICABILITY

We provide a polyimide-metal laminated body and polyimide circuit board which have satisfactory cohesion in wet plating steps, maintain practical cohesion even after high temperature aging treatment, and exhibit satisfactory electrical insulating reliability, and thus, is industrially applicable.

1. A process for producing a polyimide-metal laminated body comprising forming a metal conductive layer on a polyimide film having a ceramic-modified or pseudoceramic-modified surface with a wet plating process which comprises forming at least a ground treatment layer by electroless plating, conducting electroless metal plating and conducting electrolytic copper plating.

2. The process according to claim 1, wherein forming the ground treatment layer forms an electroless metal oxide ground layer or an electroless nickel ground layer which can be removed by etching treatment.

3. The process according to claim 1, wherein the wet plating process comprises a catalyst addition before forming the ground treatment layer.

4. The process according to claim 3, wherein the catalyst addition comprises immersion in a palladium activating solution at pH 1-5 containing a water-soluble Pd and an acid.

5. The process according to claim 3, wherein the catalyst addition comprises immersion in a palladium activating solution at pH 1-5 containing 0.01-1 g/L of a water-soluble Pd salt and 0.01-1 mL/L of an acid at 10-50° C. for 5 seconds to 5 minutes.

6. The process according to claim 1, wherein the polyimide film having a ceramic-modified or pseudoceramic-modified surface is obtained by coating a self-supporting film obtained from a solution of a polyamic acid as a polyimide precursor with a solution comprising a ceramic component comprising an aluminum compound or silica and then drying it to obtain a dry film containing the ceramic component, and then heating the obtained dry film at a temperature of 420° C. or higher to complete imidization.

7. The process according to claim 6, wherein the aluminum compound is soluble in the polyamic acid solution.

8. The process according to claim 1, wherein the polyimide-metal laminated body is further subjected to heat treatment at 100-350° C. for 1 minute to 10 hours after the wet plating.

9. The process according to claim 1, wherein the polyimide metal laminated body has an initial peel strength of the metal layer of the metal conductive layer with respect to the polyimide film of at least 0.5 kg/cm in a 90° peel test of 5 cm/minute, and is also at least 0.5 kg/cm even after aging treatment in 150° C. air for 1 week (168 hours).

10. The process according to claim 1, wherein the polyimide comprises an aromatic tetracarboxylic acid component such as 3,4,3′,4′-biphenyltetracarboxylic dianhydride and/or pyromellitic dianhydride and an aromatic diamine component comprising paraphenylene diamine and/or 4,4′-diaminophenylether.

11. The process according to claim 1, wherein the west plating process comprises degreasing/surface modification, catalyst addition, ground treatment layer forming for electroless plating, electroless metal plating and electrolytic copper plating.

12. A process for producing a polyimide circuit board by forming a circuit on a polyimide film having a ceramic-modified or pseudoceramic-modified surface by a wet plating process comprising forming at least a ground treatment layer step for electroless plating, electroless metal plating and electrolytic copper plating, and the circuit is formed by forming a photosensitive resist layer before electrolytic copper plating or during electrolytic copper plating and then removing the resist at pattern-forming sections by a photoprocess and growing electrolytic copper plating at the removed sections.

13. The process according to claim 12, wherein the unwanted resist is removed with an alkali solution and further the unwanted electroless metal plating layer and ground treatment layer at non-pattern-forming sections are removed by microetching.

14. The process according to claim 12, wherein the ground treatment layer forming for electroless plating comprises forming an electroless metal oxide ground layer or electroless nickel ground layer which can be removed by etching treatment.

15. The process according to claim 12, wherein the wet plating process comprises catalyst addition before ground treatment layer forming.

16. The process according to claim 15, wherein the catalyst addition comprises immersion in a palladium activating solution at pH 1-5 containing a water-soluble Pd and an acid.

17. The process according to claim 15, wherein the catalyst addition comprises immersion in a palladium activating solution at pH 1-5 containing 0.01-1 g/L of a water-soluble Pd salt and 0.01-1 mL/L of an acid at 10-50° C. for 5 seconds to 5 minutes.

18. The process according to claim 12, wherein the polyimide film having a ceramic-modified or pseudoceramic-modified surface is obtained by coating a self-supporting film obtained from a solution of a polyamic acid as a polyimide precursor with a solution comprising a ceramic component comprising an aluminum compound or silica and then drying it to obtain a dry film containing the ceramic component, and then heating the obtained dry film at a temperature of 420° C. or higher to complete imidization.

19. The process according to claim 18, wherein the aluminum compound is soluble in the polyamic acid solution.

20. The process according to claim 12, wherein the polyimide circuit board body is further subjected to heat treatment at 100-350° C. for 1 minute to 10 hours after the wet plating.

21. The process according to claim 12, wherein the polyimide circuit board has an initial peel strength of the metal layer of the metal conductive layer with respect to the polyimide film of at least 0.5 kg/cm in a 90° peel test of 5 cm/minute, and is also at least 0.5 kg/cm even after aging treatment in 150° C. air for 1 week (168 hours).

22. The process according to claim 12, wherein the polyimide comprises an aromatic tetracarboxylic acid component such as 3,4,3′,4′-biphenyltetracarboxylic dianhydride and/or pyromellitic dianhydride and an aromatic diamine component comprising paraphenylene diamine and/or 4,4′-diaminophenylether.

23. The process according to claim 12, wherein the wet plating process comprises degreasing/surface modification, catalyst addition, ground treatment layer forming for electroless plating, electroless metal plating and electrolytic copper plating.
